(19) United States
(12) Patent Application Publication
(10) Pub. No.: US 2019/0195940 A1
(43) Pub. Date: Jun. 27, 2019

(54) DETECTING CIRCUIT AND DISPLAY PANEL

(71) Applicant: SHENZHEN CHINA STAR OPTOELECTRONICS TECHNOLOGY CO., LTD., Shenzhen (CN)

(72) Inventor: Shuai CHEN, Shenzhen (CN)

(21) Appl. No.: 16/003,625

(22) Filed: Jun. 8, 2018

Related U.S. Application Data
(63) Continuation of application No. PCT/CN2018/072887, filed on Jan. 16, 2018.

(30) Foreign Application Priority Data
Dec. 26, 2017 (CN) 201711432941.2

(51) Int. Cl. G01R 31/28; G09G 3/36

(52) U.S. Cl. CPC G01R 31/2825; G09G 2310/0281; G09G 3/3677

(57) ABSTRACT

A detecting circuit and display panel is provided. The detecting circuit is configured to apply to an array substrate comprising a gate driver on array (GOA) circuit, wherein the GOA circuit comprises a first GOA module and a second GOA module arranged at two sides of a display area of the array substrate. The detecting circuit comprises: a driving signal output module, a first switch module and a switch control module; a first terminal of the first switch module is connected to an output terminal of the driving signal output module, a second terminal of the first switch module is connected to an input terminal of the first GOA module, a control terminal of the first switch module is connected to a first control output terminal of the switch control module, and the first control output terminal is configured to control turning on/off of the first switch module.

### RELATED APPLICATIONS

This application is a continuation application of PCT Patent Application No. PCT/CN2018/072887, filed Jan. 16, 2018, which claims the priority benefit of Chinese Patent Application No. 201711432941.2, filed Dec. 26, 2017, which is herein incorporated by reference in its entirety.

### FIELD OF THE DISCLOSURE

The disclosure relates to a display apparatus field, and more particularly to a detecting circuit and display panel.

### BACKGROUND

In today's society, thin film transistor liquid crystal display (TFT LCD) has been widely used in all aspects of our lives, there are dozens of processes for manufacturing the LCD panel, and each process is accompanied by industrial production process yield problems and reliability issues. Therefore, testing procedures after every process is an important part of industrial productivity improvement.

Gate Driver on Array (GOA) technology is a driving method for gate-by-gate scanning by fabricate a gate driving circuit on a thin film transistor array substrate through using an array process of a liquid crystal panel. The array substrate gate driving circuit (i.e., GOA circuit) has the advantages of being able to reduce the production cost and realizing the narrow bezel design and is suitable for a liquid crystal panel.

For the display panel currently using the GOA technology, the gate line signals are provided through the gate driver on array circuit (i.e., GOA circuit) integrated on two sides of the display panel. The display panel can be lit up when either one of the GOA circuit is normal. Therefore, it is difficult to detect whether the GOA circuit on a specific side is malfunctioned.

### SUMMARY

The embodiments of the present disclosure provide a detecting circuit and display panel. The detecting circuit is capable of detecting whether the GOA circuit on a specific side of the display panel is malfunctioned, so that the efficiency of GOA circuit detection is improved, thereby further improving the efficiency of the TFT LCD manufacturing process.

One embodiment of the present disclosure provides a detecting circuit being configured to apply to an array substrate comprising a gate driver on array (GOA) circuit, wherein the GOA circuit comprises a first GOA module and a second GOA module arranged at two sides of a display area of the array substrate, and the display area is lit up when a driving signal is input to either the first GOA module or the second GOA module; the detecting circuit comprises: a driving signal output module, a first switch module and a switch control module; a first terminal of the first switch module is connected to an output terminal of the driving signal output module, a second terminal of the first switch module is connected to an input terminal of the first GOA module, a control terminal of the first switch module is connected to a first control output terminal of the switch control module; and the first control output terminal is configured to control turning on/off of the first switch module.

Embodiments of the present disclosure further provide a display panel comprising the detecting circuit described above.

The beneficial effects of the embodiments of the present disclosure are as follows:

The detecting circuit provided by the embodiments of the present disclosure adds a switch module between the driving signal output module and one of the GOA modules; and, when the switch module is turned off, another GOA module can be detected to determine whether it is malfunctioned. Accordingly, the detecting circuit provided by the embodiments of the present disclosure is capable of detecting whether the GOA circuit on a specific side of the display panel is malfunctioned, so that the efficiency of GOA circuit detection is improved, thereby further improving the efficiency of the TFT LCD manufacturing process.

### BRIEF DESCRIPTION OF THE DRAWINGS

In order to make the descriptions of the technique solutions of the embodiments of the present invention or the existed techniques, the drawings necessary for describing the embodiments are briefly introduced below.

FIG. 1 is a schematic diagram of an array substrate using GOA technology provided by the present disclosure.

FIG. 2 is a schematic diagram of a detecting circuit provided by one embodiment of the present disclosure.

FIG. 3 is a schematic diagram of another detecting circuit provided by one embodiment of the present disclosure.

FIG. 4 is a schematic diagram of another detecting circuit provided by one embodiment of the present disclosure.

FIG. 5 is a schematic diagram of another detecting circuit provided by one embodiment of the present disclosure.

FIG. 6 is a schematic diagram of another detecting circuit provided by one embodiment of the present disclosure.

FIG. 7 is a schematic diagram of another detecting circuit provided by one embodiment of the present disclosure.

FIG. 8 is a schematic diagram of another detecting circuit provided by one embodiment of the present disclosure.

FIG. 9 is a schematic diagram of another detecting circuit provided by one embodiment of the present disclosure.

FIG. 10 is a schematic diagram of an inverter provided by one embodiment of the present disclosure.

FIG. 11 is a schematic diagram of another detecting circuit provided by one embodiment of the present disclosure.

### DETAILED DESCRIPTION OF PREFERRED EMBODIMENTS

The technical solutions in the embodiments of the present disclosure are clearly and completely described below with reference to the accompanying drawings in the embodiments of the present disclosure. Obviously, the described embodiments are only a part of the embodiments of the present disclosure, rather than all the embodiments. All other embodiments obtained by persons of ordinary skill in the art based on the embodiments of the present disclosure without creative efforts shall fall within the protection scope of the present application.

Gate Driver on Array (GOA) technology is a driving method for gate-by-gate scanning by fabricate a gate driving circuit on a thin film transistor array substrate through using an array process of a liquid crystal panel.

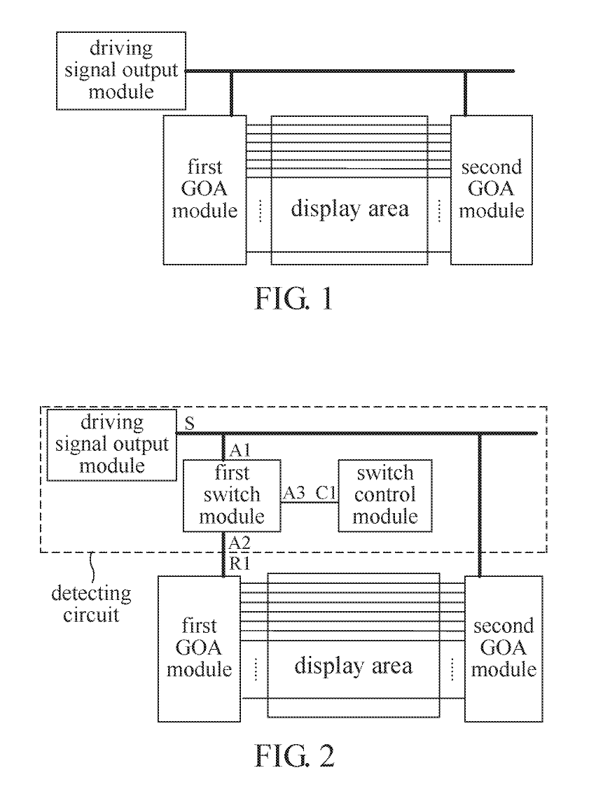

Please refer to FIG. 1. FIG. 1 is a schematic diagram of an array substrate using GOA technology provided by the present disclosure. It could be found that the gate line signals are provided by the GOA modules integrated on two sides of the display area, and the display area could be lit up by inputting driving signal to either the first GOA module or the second GOA module. Therefore, it is hard to detect whether the GOA module on a specific side is malfunctioned. For example, when the first GOA is malfunctioned and the second GOA is normal, the display area is lit up when the driving signal output module outputs the driving signal; when the second GOA is malfunctioned and the first GOA is normal, the display area is also lit up when the driving signal output module outputs the driving signal. Therefore, it is impossible to determine which one of the two GOA driving modules is malfunctioned.

Please refer to FIG. 2, which is a schematic diagram of a detecting circuit provided by one embodiment of the present disclosure. The detecting circuit is configured to apply to an array substrate comprising a GOA circuit, wherein the GOA circuit comprises a first GOA module and a second GOA module arranged at two sides of a display area of the array substrate, and the display area is lit up when a driving signal is input to either the first GOA module or the second GOA module.

The detecting circuit comprises a driving signal output module, a first switch module and a switch control module. A first terminal A1 of the first switch module is connected to an output terminal S of the driving signal output module, a second terminal A2 of the first switch module is connected to an input terminal R1 of the first GOA module, a control terminal A3 of the first switch module is connected to a first control output terminal C1 of the switch control module, and the first control output terminal C1 is configured to control turning on/off of the first switch module.

In the embodiment, when the first control output terminal C1 of the switch control module outputs a turn-off signal, the first switch module is turned off, the driving signal output from the driving signal output module cannot be transmitted to the first GOA module, and the display area can be lit up only by the driving signal transmitted through the second GOA module. Therefore, the second GOA module can be detected to determine whether it is malfunctioned (that is, the second GOA module is normal when the display area is lit up, and the second GOA module is malfunctioned when the display area is not lit up).

It can be understood that, the detecting circuit provided by the embodiments of the present disclosure adds a switch module between the driving signal output module and one of the GOA modules, and, when the switch module is turned off, another GOA module can be detected to determine whether it is malfunctioned. Accordingly, the detecting circuit provided by the embodiments of the present disclosure is capable of detecting whether the GOA circuit on a specific side of the display panel is malfunctioned, so that the efficiency of GOA circuit detection is improved, thereby further improving the efficiency of the thin film transistor liquid crystal display (TFT LCD) manufacturing process.

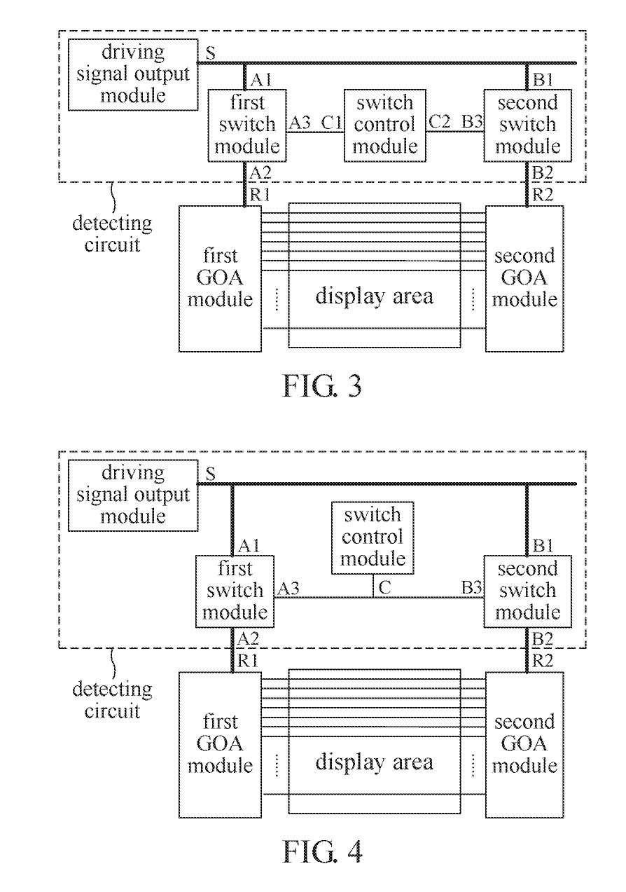

A selectable implementation is shown in FIG. 3, which is a schematic diagram of another detecting circuit provided by one embodiment of the present disclosure. Compared with the detecting circuit shown in FIG. 2, the detecting circuit shown in FIG. 3 further comprises a second switch module. A first terminal B1 of the second switch module is connected to the output terminal S of the driving signal output module, a second terminal B2 of the second switch module is connected to an input terminal R2 of the second GOA module, a control terminal B3 of the second switch module is connected to a second control output terminal C2 of the switch control module, and the second control output terminal C2 is configured to control turning on/off of the second switch module.

In the embodiment, when the first control output terminal C1 of the switch control module outputs the turn-off signal and the second control output terminal C2 outputs the turn-on signal, the first switch module is turned off and the second switch module is turned on, the driving signal output from the driving signal output module cannot be output to the first GOA module but can be output to the second GOA to achieve the goal of lighting up the display area. Therefore, the second GOA module can be detected to determine whether it is malfunctioned (that is, the second GOA module is normal when the display area is lit up, and the second GOA module is malfunctioned when the display area is not lit up).

It can be understood that, the detecting circuit provided by the present embodiment can be used to detect whether the GOA circuit on any side of the display panel is malfunctioned.

In one selectable implementation, the first control output terminal C1 and the second control output terminal C2 is the same switch control output terminal C. The switch control output terminal C is configured to output a first control signal, and the first control signal is used for turning on the first switch module and turning off the second switch module.

For example, as shown in FIG. 4, which is a schematic diagram of another detecting circuit provided by one embodiment of the present disclosure, the first switch module is a high level conducted switch module and the second switch module is a low level conducted switch module. When the switch control output terminal outputs a high level signal, the first switch module is turned on and the second switch is turned off, the driving signal output from the driving signal output module cannot be output to the second GOA module, and the display panel can be lit up by the driving signal through the first GOA module, so that the first GOA module can be detected to determine whether it is malfunctioned.

It can be understood that, the detecting circuit provided in the embodiment can be used to detect whether the GOA circuit on any side of the display panel is malfunctioned when there is only one switch control output terminal in the switch control module.

In one selectable implementation, the first control output terminal C1 and the second control output terminal C2 is the same one switch control output terminal C, and the detecting circuit further comprises an inverter. An input terminal F1 of the inverter and the control terminal B3 of the second switch module are connected to the switch control output terminal C, and an output terminal F2 of the inverter is connected to the control terminal A3 of the first switch module. The switch control output terminal is configured to output a second control signal or a third control signal, the second control signal is used for turning off the first switch module and the second switch module, and the third control signal is used for turning on the first switch module and the second switch module. The inverter is configured to convert the received second control signal to the third control signal or convert the received third control signal to the second control signal.

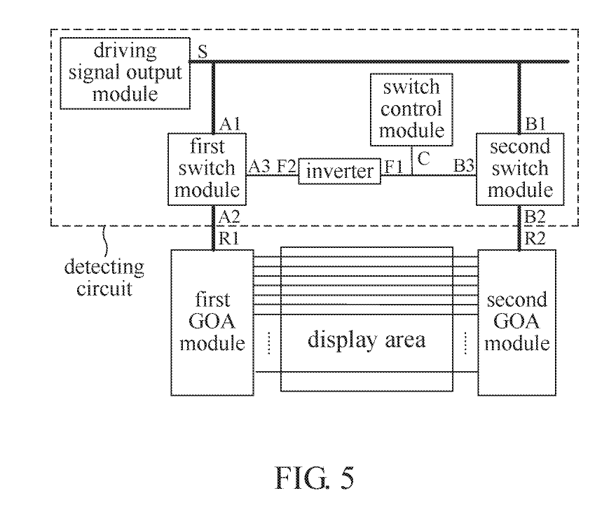

For example, as shown in FIG. 5, which is a schematic diagram of another detecting circuit provided by one embodiment of the present disclosure, the first switch module and the second switch module are both high level conducted switch modules. When the switch control output terminal outputs a high level signal, the inverter converts the high level signal to a low level signal, so that the first switch module is turned off and the second switch is turned on. The driving signal output from the driving signal output module cannot be output to the first GOA module but can be output to the second GOA to achieve the goal of lighting up the display area. Therefore, the second GOA module can be detected to determine whether it is malfunctioned. When the switch control output terminal outputs a low level signal, the inverter converts the low level signal to a high level signal, so that the first switch module is turned on and the second switch is turned off. The driving signal output from the driving signal output module cannot be output to the second GOA module but can be output to the first GOA to achieve the goal of lighting up the display area. Therefore, the first GOA module can be detected to determine whether it is malfunctioned. Similarly, the first switch module and the second switch module can be low level conducted switch modules. The implementations of detecting are similar to those described above for the high level conducted switch modules and are not described in detail here.

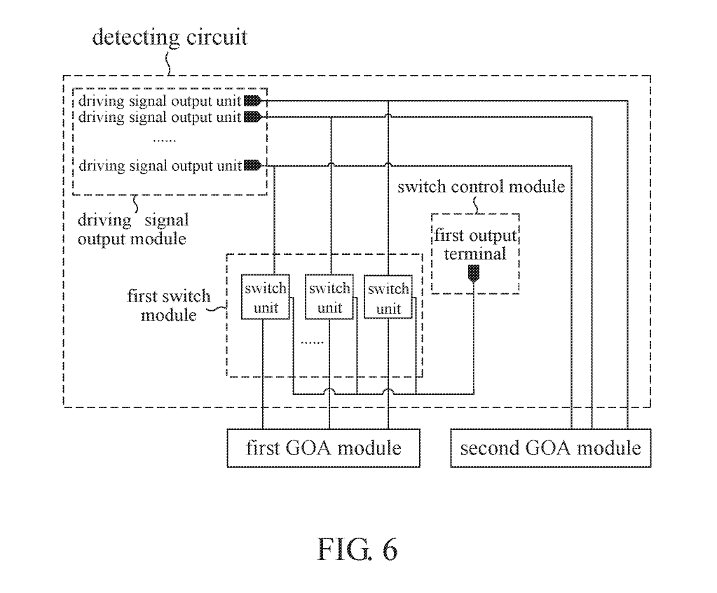

Please refer to FIG. 6, which is a schematic diagram of another detecting circuit provided by one embodiment of the present disclosure. The detecting circuit is configured to apply to an array substrate comprising a GOA circuit, wherein the GOA circuit comprises a first GOA module and a second GOA module arranged at two sides of a display area of the array substrate, and the display area is lit up when a driving signal is input to either the first GOA module or the second GOA module.

The detecting circuit comprises a driving signal output module, a first switch module and a switch control module. The driving signal output module comprises at least one driving signal output unit, and the first switch module comprises at least one switch unit. A first terminal of the switch unit of the first switch module is correspondingly connected to an output terminal of the driving signal output unit of the driving signal output module, a second terminal of the switch unit of the first switch module is correspondingly connected to an input terminal of the first GOA module, a control terminal of the switch unit of the first switch module is connected to a first control output terminal of the switch control module, and the first control output terminal is configured to control turning on/off of the switch unit of the first switch module.

In the embodiment, when the first control output terminal of the switch control module outputs a turn-off signal, all the switch unit(s) of the first switch module is turned off, the driving signal output from the driving signal output module cannot be transmitted to the first GOA module, and the display area can be lit up only by the driving signal transmitted through the second GOA module. Therefore, the second GOA module can be detected to determine whether it is malfunctioned (that is, the second GOA module is normal when the display area is lit up, and the second GOA module is malfunctioned when the display area is not lit up).

In the present embodiment, the signals of the gate driver on array circuit (GOA circuit) generally comprises a clock trigger signal STV, a clock signal CK, a low level signal VSS and high level signals LC1 and LC2. Therefore, the driving signal output module could comprise a clock trigger signal output unit, a clock signal output unit, a low level signal output unit, a first high level signal output unit and a second high level signal output unit. The first switch module comprises switching units correspondingly connected to the signal output units to control whether the signals are input to the corresponded GOA module.

It can be understood that, in the detecting circuit provided in the present embodiment, the driving signal output module comprises at least one driving signal output unit, each driving signal output unit is connected to a corresponded GOA module, and a switch unit is correspondingly set between any GOA module and the corresponded driving signal output unit, and another GOA module can be detected to determine whether it is malfunctioned when the switch units are turned off. Therefore, the detecting circuit provided by the present embodiment is capable of detecting whether the GOA circuit on any side of the display panel is malfunctioned, so that the efficiency of GOA circuit detection is improved, thereby further improving the efficiency of the TFT LCD manufacturing process.

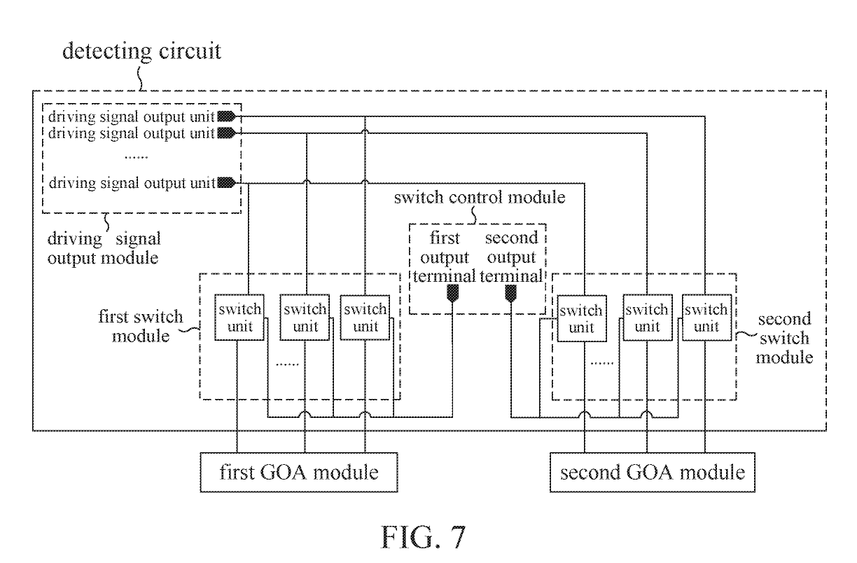

A selectable implementation is shown in FIG. 1, which is a schematic diagram of another detecting circuit provided by one embodiment of the present disclosure. Compared with the detecting circuit shown in FIG. 6, the detecting circuit shown in FIG. 7 further comprises a second switch module, and the second switch module comprises at least one switch unit. A first terminal of the switch unit of the second switch module is correspondingly connected to the output terminal of the driving signal output module, a second terminal of the switch unit of the second switch module is correspondingly connected to an input terminal of the second GOA module, a control terminal of the switch unit of the second switch module is connected to a second control output terminal of the switch control module, and the second control output terminal is configured to control turning on/off of the second switch module.

In the embodiment, when the first control output terminal of the switch control module outputs the turn-off signal and the second control output terminal outputs the turn-on signal, the switch unit(s) of the first switch module is (are) turned off and the switch unit(s) of the second switch module is (are) turned on, the driving signal output from the driving signal output module cannot be output to the first GOA module but can be output to the second GOA to achieve the goal of lighting up the display area. Therefore, the second GOA module can be detected to determine whether it is malfunctioned (that is, the second GOA module is normal when the display area is lit up, and the second GOA module is malfunctioned when the display area is not lit up).

It can be understood that, the detecting circuit provided by the present embodiment can be used to detect whether the GOA circuit on any side of the display panel is malfunctioned.

In one selectable implementation, the first control output terminal and the second control output terminal is the same switch control output terminal. The switch control output terminal is configured to output a first control signal, and the first control signal is used for turning on the switch unit of the first switch module and turning off the switch unit of the second switch module.

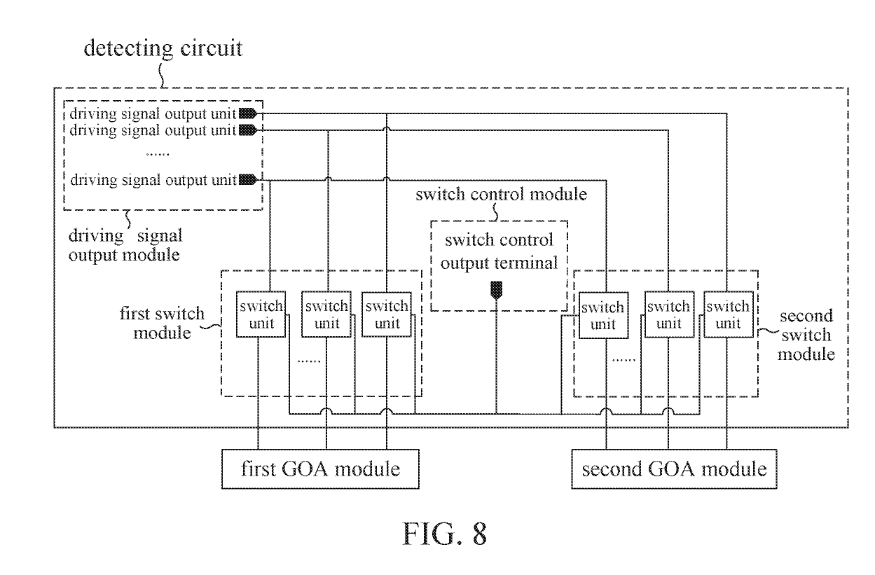

For example, as shown in FIG. 8, which is a schematic diagram of another detecting circuit provided by one embodiment of the present disclosure, each switch unit of the first switch module is a high level conducted switch module and each switch unit of the second switch module is a low level conducted switch module. When the switch control output terminal outputs a high level signal, all the switch unit(s) of the first switch module is (are) turned on and all the switch unit(s) of the second switch is (are) turned off, the driving signal output from the driving signal output module cannot be output to the second GOA module, and the display panel can be lit up by the driving signal through the first GOA module, so that the first GOA module can be detected to determine whether it is malfunctioned.

It can be understood that, the detecting circuit provided in the embodiment can be used to detect whether the GOA circuit on any side of the display panel is malfunctioned when there is only one switch control output terminal in the switch control module.

In one selectable implementation, the first control output terminal and the second control output terminal is the same one switch control output terminal, and the detecting circuit further comprises an inverter. An input terminal of the inverter and the control terminal of the switch unit of the first switch module are connected to the switch control output terminal, and an output terminal of the inverter is connected to the control terminal of the switch unit of the second switch module. The switch control output terminal is configured to output a second control signal or a third control signal, the second control signal is used for turning off the switch unit(s) of the first switch module and the switch unit(s) of the second switch module, and the third control signal is used for turning on the switch unit(s) of the first switch module and the switch unit(s) of the second switch module. The inverter is configured to convert the received second control signal to the third control signal or convert the received third control signal to the second control signal.

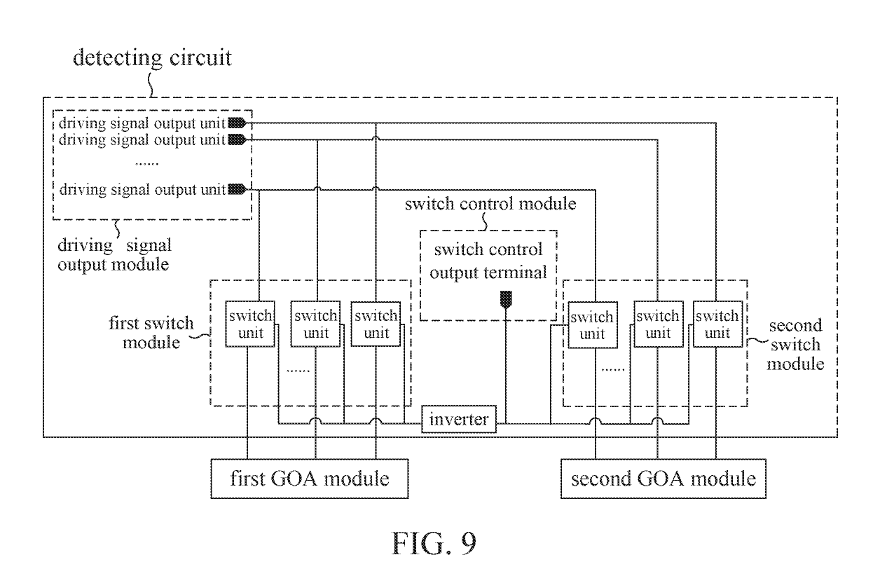

For example, as shown in FIG. 9, which is a schematic diagram of another detecting circuit provided by one embodiment of the present disclosure, the switch unit(s) of the first switch module and the switch unit(s) of the second switch module are high level conducted switch modules. When the switch control output terminal outputs a high level signal, the inverter converts the high level signal to a low level signal, so that the switch unit(s) of the first switch module is (are) turned off and the switch unit(s) of the second switch is (are) turned on. The driving signal output from the driving signal output module cannot be output to the first GOA module but can be output to the second GOA to achieve the goal of lighting up the display area. Therefore, the second GOA module can be detected to determine whether it is malfunctioned. When the switch control output terminal outputs a low level signal, the inverter converts the low level signal to a high level signal, so that the switch unit(s) of the first switch module is (are) turned on and the switch unit(s) of the second switch is (are) turned off. The driving signal output from the driving signal output module cannot be output to the second GOA module but can be output to the first GOA to achieve the goal of lighting up the display area. Therefore, the first GOA module can be detected to determine whether it is malfunctioned. Similarly, the switch unit(s) of the first switch module and the switch unit(s) of the second switch module can be low level conducted switch modules. The implementations of detecting are similar to those described above for the high level conducted switch modules and are not described in detail here.

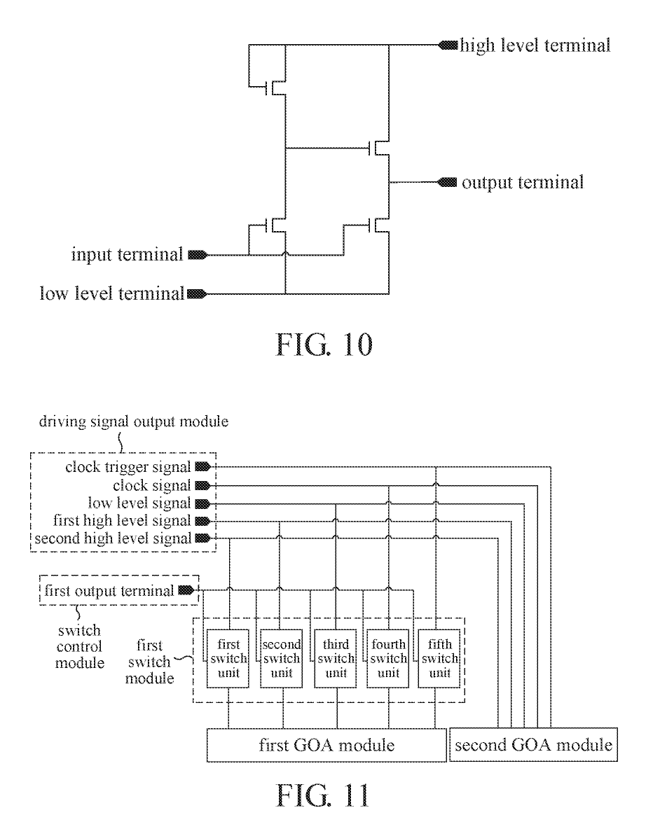

In the present embodiment, the inverter could be a Darlington Reverser shown in FIG. 10. The high level terminal of the Darlington Reverser is connected to the first high level signal output unit LC1 or the second high level signal output unit LC2 of the driving signal output module, and the low level terminal of the Darlington Reverser is connected to the low level signal output unit VSS.

Please refer to FIG. 11, which is a schematic diagram of another detecting circuit provided by one embodiment of the present disclosure. The detecting circuit is configured to apply to an array substrate comprising a GOA circuit, wherein the GOA circuit comprises a first GOA module and a second GOA module arranged at two sides of a display area of the array substrate, and the display area is lit up when a driving signal is input to either the first GOA module or the second GOA module.

The detecting circuit comprises a driving signal output module, a first switch module and a switch control module. The driving signal output module comprises a clock trigger signal output unit, a clock signal output unit, a low level signal output unit, a first high level signal output unit and a second high level signal output unit.

The first switch module comprises a first switch unit, a second switch unit, a third switch unit, a fourth switch unit and a fifth switch unit. A first terminal of the first switch unit is connected to an output terminal of the clock trigger signal output unit, a first terminal of the second switch unit is connected to an output terminal of the clock signal output unit, a first terminal of the third switch unit is connected to an output terminal of the low level signal output terminal, a first terminal of the fourth switch unit is connected to an output terminal of the first high level signal output unit, and a first terminal of the fifth switch unit is connected to an output terminal of the second high level signal output unit. A second terminal of the first switch unit, a second terminal of the second switch unit, a second terminal of the third switch unit, a second terminal of the fourth switch unit and a second terminal of the fifth switch unit are connected to the input terminal of the first GOA module. A control terminal of the first switch unit, a control terminal of the second switch unit, a control terminal of the third switch unit, a control terminal of the fourth switch unit and a control terminal of the fifth switch unit are connected to the first control output terminal of the switch control module. The first control output terminal is configured to control turning on/off of the switch units of the first switch module.

In the present embodiment, when the first control output terminal of the switch control module outputs the turn-off signal, the first switch unit, the second switch unit, the third switch unit, the fourth switch unit and the fifth switch unit of the first switch module are turned off, the clock trigger signal STV, the clock signal CK, the low level signal VSS, the first high level signal LC1 and the second high level signal LC2 of the driving signal output module cannot be transmitted to the first GOA module, and the driving signals can be transmitted through the second GOA module to light up the display panel. Therefore, the second GOA module can be detected to determine whether it is malfunctioned (that is, the second GOA module is normal when the display area is lit up, and the second GOA module is malfunctioned when the display area is not lit up).

It can be understood that, in the detecting circuit provided by the present embodiment, the driving signal output module comprises five driving signal output units, each driving signal output unit is connected to the corresponded GOA module, the switch units are set between the driving signal output units and one of the GOA modules, and another one of the GOA modules can be detected to determined whether it is malfunctioned when the switch units are turned off. Accordingly, the detecting circuit provided by the embodiments of the present disclosure is capable of detecting whether the GOA circuit on a specific side of the display panel is malfunctioned, so that the efficiency of GOA circuit detection is improved, thereby further improving the efficiency of the TFT LCD manufacturing process.

The embodiments of the present disclosure also provide a display panel comprising any one of the detecting circuits described above.

In the present embodiment, the display panel comprises an array substrate comprising the GOA circuit.

The embodiments of the present disclosure further provide a display device, the display device comprises any one of the display panel described above.

In the embodiments, the display device may be a device provided with a TFT LCD or an organic light emitting diode display (OLED), such as a cell phone, a tablet computer, a television, a computer and the like.

The detecting circuit provided by the embodiments of the present disclosure are described in detail as above. Specific examples are used herein to describe the principle and implementation manners of the present application. The description of the foregoing embodiments is merely used to help understand the method and core idea of the present application. Meanwhile, for those skilled in the art, according to the present invention, the specific implementation manners and the scope of application of the idea may be changed. In conclusion, the content of the description should not be construed as a limitation on the present invention.

What is claimed is:

1. A detecting circuit being configured to apply to an array substrate comprising a gate driver on array (GOA) circuit, wherein the GOA circuit comprises a first GOA module and a second GOA module arranged at two sides of a display area of the array substrate, and the display area is lit up when a driving signal is input to either the first GOA module or the second GOA module;
the detecting circuit comprises: a driving signal output module, a first switch module and a switch control module; a first terminal of the first switch module is connected to an output terminal of the driving signal output module, a second terminal of the first switch module is connected to an input terminal of the first GOA module, a control terminal of the first switch module is connected to a first control output terminal of the switch control module, and the first control output terminal is configured to control turning on/off of the first switch module.

2. The detecting circuit according to claim 1, wherein the detecting circuit further comprises a second switch module; a first terminal of the second switch module is connected to the output terminal of the driving signal output module, a second terminal of the second switch module is connected to an input terminal of the second GOA module, a control terminal of the second switch module is connected to a second control output terminal of the switch control module, and the second control output terminal is configured to control turning on/off of the second switch module.

3. The detecting circuit according to claim 2, wherein the first control output terminal and the second control output terminal is a same one switch control output terminal, and the switch control output terminal is configured to output a first control signal to turn on the first switch module and turn off the second switch module.

4. The detecting circuit according to claim 2, wherein the first control output terminal and the second control output terminal is a same one switch control output terminal, and the detecting circuit further comprises an inverter;
an input terminal of the inverter and the control terminal of the second switch module are connected to the switch control output terminal, and an output terminal of the inverter is connected to the control terminal of the first switch module;
the switch control output terminal is configured to output a second control signal or a third control signal, the second control signal is used for turning off the first switch module and the second switch module, and the third control signal is used for turning on the first switch module and the second switch module;
the inverter is configured to convert the received second control signal to the third control signal or convert the received third control signal to the second control signal.

5. The detecting circuit according to claim 1, wherein the driving signal output module comprises at least one driving signal output unit, the first switch module comprises at least one switch unit, a first terminal of the switch unit of the first switch module is correspondingly connected to an output terminal of the driving signal output unit of the driving signal output module, a second terminal of the switch unit of the first switch module is correspondingly connected to the input terminal of the first GOA module, a control terminal of the switch unit of the first switch module is connected to the first control output terminal of the switch control module, and the first control output terminal is configured to control turning on/off of the switch unit of the first switch module.

6. The detecting circuit according to claim 5, wherein the detecting circuit further comprises a second switch module, the second switch module comprises at least one switch unit; a first terminal of the switch unit of the second switch module is correspondingly connected to the output terminal of the driving signal output unit of the driving signal output module, a second terminal of the switch unit of the second switch module is correspondingly connected to an input terminal of the second GOA module, a control terminal of the switch unit of the second switch module is connected to a second control output terminal of the switch control module, and the second control output terminal is configured to control turning on/off of the switch unit of the second switch module.

7. The detecting circuit according to claim 6, wherein the first control output terminal and the second control output terminal is a same one switch control output terminal, and the switch control output terminal is configured to output a first control signal to turn on the switch unit of the first switch module and turn off the switch unit of the second switch module.

8. The detecting circuit according to claim 6, wherein the first control output terminal and the second control output terminal is a same one switch control output terminal, and the detecting circuit further comprises an inverter;
an input terminal of the inverter and the control terminal of the switch unit of the first switch module are connected to the switch control output terminal, and an output terminal of the inverter is connected to the control terminal of the switch unit of the second switch module;
the switch control output terminal is configured to output a second control signal or a third control signal, the second control signal is used for turning off the switch unit of the first switch module and the switch unit of the second switch module, and the third control signal is used for turning on the switch unit of the first switch module and the switch unit of the second switch module;
the inverter is configured to convert the received second control signal to the third control signal or convert the received third control signal to the second control signal.

9. The detecting circuit according to claim 1, wherein the driving signal output module comprises: a clock trigger signal output unit, a clock signal output unit, a low level signal output unit, a first high level signal output unit and a second high level signal output unit;
the first switch module comprises a first switch unit, a second switch unit, a third switch unit, a fourth switch unit and a fifth switch unit; a first terminal of the first switch unit is connected to an output terminal of the clock trigger signal output unit, a first terminal of the second switch unit is connected to an output terminal of the clock signal output unit, a first terminal of the third switch unit is connected to an output terminal of the low level signal output terminal, a first terminal of the fourth switch unit is connected to an output terminal of the first high level signal output unit, and a first terminal of the fifth switch unit is connected to an output terminal of the second high level signal output unit; a second terminal of the first switch unit, a second terminal of the second switch unit; a second terminal of the third switch unit; a second terminal of the fourth switch unit and a second terminal of the fifth switch unit are connected to the input terminal of the first GOA module; a control terminal of the first switch unit, a control terminal of the second switch unit, a control terminal of the third switch unit, a control terminal of the fourth switch unit and a control terminal of the fifth switch unit are connected to the first control output terminal of the switch control module.

10. A display panel comprising a detecting circuit, the detecting circuit being configured to apply to an array substrate comprising a gate driver on array (GOA) circuit, wherein the GOA circuit comprises a first GOA module and a second GOA module arranged at two sides of a display area of the array substrate, and the display area is lit up when a driving signal is input to either the first GOA module or the second GOA module;
the detecting circuit comprises: a driving signal output module, a first switch module and a switch control module; a first terminal of the first switch module is connected to an output terminal of the driving signal output module, a second terminal of the first switch module is connected to an input terminal of the first GOA module, a control terminal of the first switch module is connected to a first control output terminal of the switch control module, and the first control output terminal is configured to control turning on/off of the first switch module.

11. The display panel according to claim 10, wherein the detecting circuit further comprises a second switch module; a first terminal of the second switch module is connected to the output terminal of the driving signal output module, a second terminal of the second switch module is connected to an input terminal of the second GOA module, a control terminal of the second switch module is connected to a second control output terminal of the switch control module, and the second control output terminal is configured to control turning on/off of the second switch module.

12. The display panel according to claim 11, wherein the first control output terminal and the second control output terminal is a same one switch control output terminal, and the switch control output terminal is configured to output a first control signal to turn on the first switch module and turn off the second switch module.

13. The display panel according to claim 11, wherein the first control output terminal and the second control output terminal is a same one switch control output terminal, and the detecting circuit further comprises an inverter;
an input terminal of the inverter and the control terminal of the second switch module are connected to the switch control output terminal, and an output terminal of the inverter is connected to the control terminal of the first switch module;
the switch control output terminal is configured to output a second control signal or a third control signal, the second control signal is used for turning off the first switch module and the second switch module, and the third control signal is used for turning on the first switch module and the second switch module;
the inverter is configured to convert the received second control signal to the third control signal or convert the received third control signal to the second control signal.

14. The display panel according to claim 10, wherein the driving signal output module comprises at least one driving signal output unit, the first switch module comprises at least one switch unit, a first terminal of the switch unit of the first switch module is correspondingly connected to an output terminal of the driving signal output unit of the driving signal output module, a second terminal of the switch unit of the first switch module is correspondingly connected to the input terminal of the first GOA module, a control terminal of the switch unit of the first switch module is connected to the first control output terminal of the switch control module, and the first control output terminal is configured to control turning on/off of the switch unit of the first switch module.

15. The display panel according to claim 14, wherein the detecting circuit further comprises a second switch module, the second switch module comprises at least one switch unit; a first terminal of the switch unit of the second switch module is correspondingly connected to the output terminal of the driving signal output unit of the driving signal output module, a second terminal of the switch unit of the second switch module is correspondingly connected to an input terminal of the second GOA module, a control terminal of the switch unit of the second switch module is connected to a second control output terminal of the switch control module, and the second control output terminal is configured to control turning on/off of the switch unit of the second switch module.

16. The display panel according to claim 15, wherein the first control output terminal and the second control output terminal is a same one switch control output terminal, and the switch control output terminal is configured to output a first control signal to turn on the switch unit of the first switch module and turn off the switch unit of the second switch module.

17. The display panel according to claim 15, wherein the first control output terminal and the second control output terminal is a same one switch control output terminal, and the detecting circuit further comprises an inverter;
an input terminal of the inverter and the control terminal of the switch unit of the first switch module are connected to the switch control output terminal, and an output terminal of the inverter is connected to the control terminal of the switch unit of the second switch module;
the switch control output terminal is configured to output a second control signal or a third control signal, the second control signal is used for turning off the switch unit of the first switch module and the switch unit of the second switch module, and the third control signal is used for turning on the switch unit of the first switch module and the switch unit of the second switch module;
the inverter is configured to convert the received second control signal to the third control signal or convert the received third control signal to the second control signal.

18. The display panel according to claim 10, wherein the driving signal output module comprises: a clock trigger signal output unit, a clock signal output unit, a low level signal output unit, a first high level signal output unit and a second high level signal output unit;
the first switch module comprises a first switch unit, a second switch unit, a third switch unit, a fourth switch unit and a fifth switch unit; a first terminal of the first switch unit is connected to an output terminal of the clock trigger signal output unit, a first terminal of the second switch unit is connected to an output terminal of the clock signal output unit, a first terminal of the third switch unit is connected to an output terminal of the low level signal output terminal, a first terminal of the fourth switch unit is connected to an output terminal of the first high level signal output unit, and a first terminal of the fifth switch unit is connected to an output terminal of the second high level signal output unit; a second terminal of the first switch unit, a second terminal of the second switch unit, a second terminal of the third switch unit, a second terminal of the fourth switch unit and a second terminal of the fifth switch unit are connected to the input terminal of the first GOA module; a control terminal of the first switch unit, a control terminal of the second switch unit, a control terminal of the third switch unit, a control terminal of the fourth switch unit and a control terminal of the fifth switch unit are connected to the first control output terminal of the switch control module.
